(19) United States
(12) Patent Application Publication
(10) Pub. No.: US 2025/0366019 A1
(43) Pub. Date: Nov. 27, 2025

(54) SEMICONDUCTOR DEVICE AND MANUFACTURING METHOD THEREOF

(71) Applicants: NIKO SEMICONDUCTOR CO., LTD., New Taipei City (TW); SUPER GROUP SEMICONDUCTOR CO., LTD., Hsinchu County (TW)

(72) Inventors: Sung-Nien TANG, Hsinchu County (TW); Ho-Tai CHEN, Hsinchu County (TW); Hsiu-Wen HSU, Hsinchu County (TW)

(21) Appl. No.: 18/959,560

(22) Filed: Nov. 25, 2024

(30) Foreign Application Priority Data
May 23, 2024 (TW) 113119086

(51) Int. Cl. H10D 30/63; H01L 21/02; H10D 30/01; H10D 62/40; H10D 62/832

(52) U.S. Cl. CPC H10D 30/63; H01L 21/02675; H10D 30/025; H10D 62/402; H10D 62/8325

(57) ABSTRACT

A manufacturing method of a semiconductor device includes forming a body region, a source region, and a contact region in a silicon carbide substrate, wherein the body region surrounds the source region and the contact region; forming an amorphous silicon layer on a top surface of the silicon carbide substrate, such that the body region and the source region are covered by the amorphous silicon layer; doping N-type dopants in the amorphous silicon layer; crystallizing the amorphous silicon layer to form a polysilicon layer; oxidizing an upper portion of the polysilicon layer such that the upper portion of the polysilicon layer defines an oxide layer, and a lower portion of the polysilicon layer defines a channel layer, wherein the thickness of the oxide layer is greater than or equal to the thickness of the channel layer; and forming a gate layer on the oxide layer.

### CROSS-REFERENCE TO RELATED APPLICATION

This application claims priority to Taiwan Application Serial Number 113119086, filed May 23, 2024, which is herein incorporated by reference.

### BACKGROUND

### Field of Invention

The present disclosure relates to a semiconductor device and a manufacturing method of the semiconductor device.

### Description of Related Art

Silicon carbide (SiC) is a high-hardness semiconductor material and has a larger bandgap than silicon (Si). Silicon carbide can be used in a variety of semiconductor devices such as power components, environmentally resistant components, high-temperature operating components, and high-frequency components, and has the advantage of reducing power loss. Through the characteristic, silicon carbide power components can realize smaller semiconductor devices than silicon power components.

The gate structure of a metal oxide semiconductor field effect transistor (MOSFET) sequentially includes a metal layer, an oxide layer, and a semiconductor layer (channel layer) from top to bottom. A silicon carbide substrate can replace a traditional silicon substrate. In general, the channel layer on the silicon carbide substrate is formed by directly oxidizing the surface of the silicon carbide substrate and inserting nitric oxide (NO) or nitrous oxide (N₂O) for annealing. However, this traditional process and structure are difficult to improve the problem of poor mobility at the interface between silicon carbide and silicon dioxide (SiO₂) (i.e., the channel mobility of a transistor).

### SUMMARY

According to some embodiments of the present disclosure, a semiconductor device includes a silicon carbide substrate, a channel layer, an oxide layer, and a gate layer. The silicon carbide substrate has a body region, a source region, and a contact region therein. The body region surrounds the source region and the contact region, and the contact region connects a bottom portion of the source region. The channel layer is located on a first top surface of the silicon carbide substrate, and covers the body region and a first portion of the source region. The oxide layer is in direct contact with a second top surface of the channel layer, wherein a thickness of the oxide layer is greater than or equal to a thickness of the channel layer. The gate layer is located on the oxide layer.

In some embodiments, the semiconductor device further includes an interlayer dielectric layer. The interlayer dielectric layer covers the gate layer and a second portion of the source region, and is in direct contact with a first sidewall of the oxide layer and a second sidewall of the channel layer.

In some embodiments, the semiconductor device further includes a metal layer. The metal layer is located on the interlayer dielectric layer and passes through the source region to connect the contact region.

In some embodiments, the semiconductor device further includes a drain layer. The drain layer is located on a bottom surface of the silicon carbide substrate.

In some embodiments, a material of the channel layer is polysilicon.

According to some embodiments of the present disclosure, a manufacturing method of a semiconductor device includes forming a body region, a source region, and a contact region in a silicon carbide substrate, wherein the body region surrounds the source region and the contact region connected to the bottom of the source region; forming an amorphous silicon layer on a top surface of the silicon carbide substrate, such that the body region and the source region are covered by the amorphous silicon layer; doping plural N-type dopants in the amorphous silicon layer; crystallizing the amorphous silicon layer to form a polysilicon layer; oxidizing an upper portion of the polysilicon layer such that the upper portion of the polysilicon layer defines an oxide layer, and a lower portion of the polysilicon layer defines a channel layer, wherein the thickness of the oxide layer is greater than or equal to the thickness of the channel layer; and forming a gate layer on the oxide layer.

In some embodiments, the body region is formed by doping a plurality of P-type dopants in the silicon carbide substrate.

In some embodiments, the N-type dopants are doped in the amorphous silicon layer by a dose of the N-type dopants in a range from 1e15 cm⁻³ to 1e17 cm⁻³. Crystallizing the amorphous silicon layer is performed by excimer laser annealing the amorphous silicon layer. Oxidizing the upper portion of the polysilicon layer is performed by a temperature in a range from 750° C. to 900° C.

In some embodiments, after the gate layer is formed on the oxide layer, the manufacturing method further includes etching the oxide layer and the channel layer that are above the source region, such that the channel layer covers a first portion of the source region, and exposes the source region except the first portion; forming an interlayer dielectric layer to cover the gate layer and a second portion of the source region, such that the interlayer dielectric layer is in direct contact with a first sidewall of the oxide layer and a second sidewall of the channel layer; etching the source region on the contact region such that the contact region is exposed; and forming a metal layer on the interlayer dielectric layer, wherein the metal layer passes through the source region to connect the contact region.

In some embodiments, before the body region, the source region, and the contact region are formed in the silicon carbide substrate, the manufacturing method further includes forming a drain layer on a bottom surface of the silicon carbide substrate.

In the aforementioned embodiments of the present disclosure, since the manufacturing method of the semiconductor device is performed by forming the amorphous silicon layer on the top surface of the silicon carbide substrate and then doping the N-type dopants in the amorphous silicon layer and crystallizing the amorphous silicon layer to form the polysilicon layer, the upper portion of the polysilicon layer can be oxidized to form the oxide layer and the lower portion of the polysilicon layer serves as the channel layer. In a subsequent process, the gate layer can be formed on the oxide layer such that the oxide layer acts as a gate dielectric layer. In other words, the stacked oxide layer and channel layers are formed from the amorphous silicon layer, and thus the channel mobility of the semiconductor device can be effectively improved to solve the typical problem of poor mobility at the interface between silicon carbide and silicon dioxide.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor device according to one embodiment of the present disclosure.

FIG. 2 is flow chart of a manufacturing method of a semiconductor device according to one embodiment of the present disclosure.

FIG. 3 to FIG. 8 are cross-sectional views at intermediate stages of a manufacturing method of a semiconductor device according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

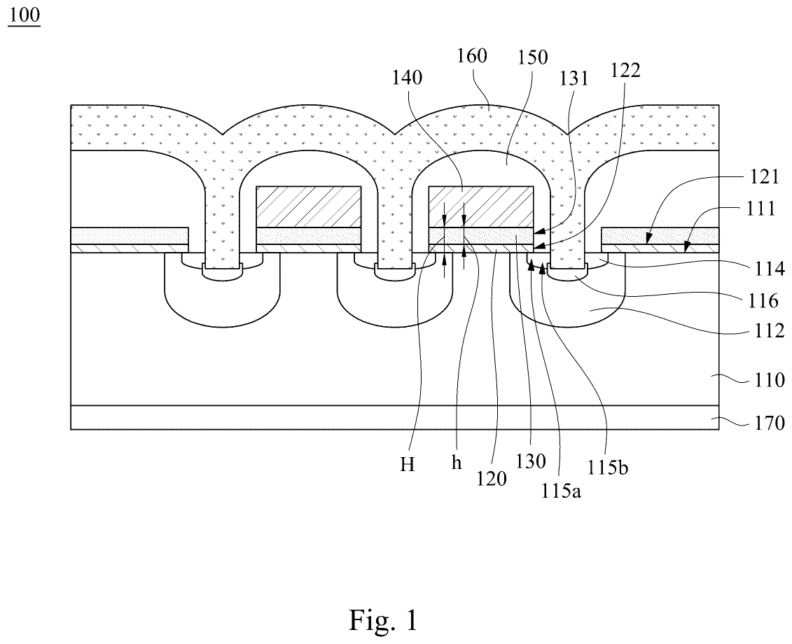

FIG. 1 is a cross-sectional view of a semiconductor device 100 according to one embodiment of the present disclosure. The semiconductor device 100 includes a silicon carbide (SiC) substrate 110, a channel layer 120, an oxide layer 130, and a gate layer 140. The silicon carbide substrate 110 has a body region 112, a source region 114, and a contact region 116 therein. The body region 112 surrounds the source region 114 and the contact region 116, and the contact region 116 connects the bottom portion of the source region 114. In some embodiments, the body region 112 and the contact region 116 may be P-type, and the source region 114 may be N-type. The channel layer 120 is located on a first top surface 111 of the silicon carbide substrate 110, and covers the body region 112 and a first portion 115a of the source region 114. The oxide layer 130 is in direct contact with a second top surface 121 of the channel layer 120. The oxide layer 130 may overlap the channel layer 120 in a vertical direction. Moreover, the thickness of the oxide layer 130 is greater than or equal to the thickness of the channel layer 120. In some embodiments, the sum of the thicknesses H of the oxide layer 130 and the channel layer 120 is in a range from 50 nm to 100 nm, and a thickness h of the oxide layer 130 is in a range from 25 nm to 60 nm. The gate layer 140 is located on the oxide layer 130.

In some embodiments, the material of the channel layer 120 is polysilicon, and the gate layer 140 is a polysilicon gate. The oxide layer 130 is a gate dielectric layer. The semiconductor device 100 is a silicon carbide metal oxide semiconductor field effect transistor (SIC MOSFET) having an embedded polysilicon channel diode (PCD). Furthermore, the semiconductor device 100 may be a power component, and can be used in the fields of vehicles (e.g., electric cars), solar inverters, etc.

The oxide layer 130 and the channel layer 120 of the semiconductor device 100 stacked from top to bottom are respectively formed from the upper portion and the lower portion of a single amorphous silicon layer (to be described later), the sum of the thicknesses H of the oxide layer 130 and the channel layer 120 is in a range from 50 nm to 100 nm, and the thickness h of the oxide layer 130 is in a range from 25 nm to 60 nm, thereby effectively improving the channel mobility of the semiconductor device 100 to solve the typical problem of poor mobility at the interface between silicon carbide and silicon dioxide.

In some embodiments, the semiconductor device 100 further includes an interlayer dielectric layer 150 and a metal layer 160. The interlayer dielectric layer 150 covers the gate layer 140 and a second portion 115b of the source region 114, and is in direct contact with a first sidewall 131 of the oxide layer 130 and a second sidewall 122 of the channel layer 120. The metal layer 160 is located on the interlayer dielectric layer 150 and passes through the source region 114 to connect the contact region 116. Moreover, the semiconductor device 100 may further include a drain layer 170. The drain layer 170 is located on the bottom surface of the silicon carbide substrate 110.

It is to be noted that the connection relationships, the materials, and the advantages of the elements described above will not be repeated in the following description. In the following description, the manufacturing method of the semiconductor device 100 will be explained.

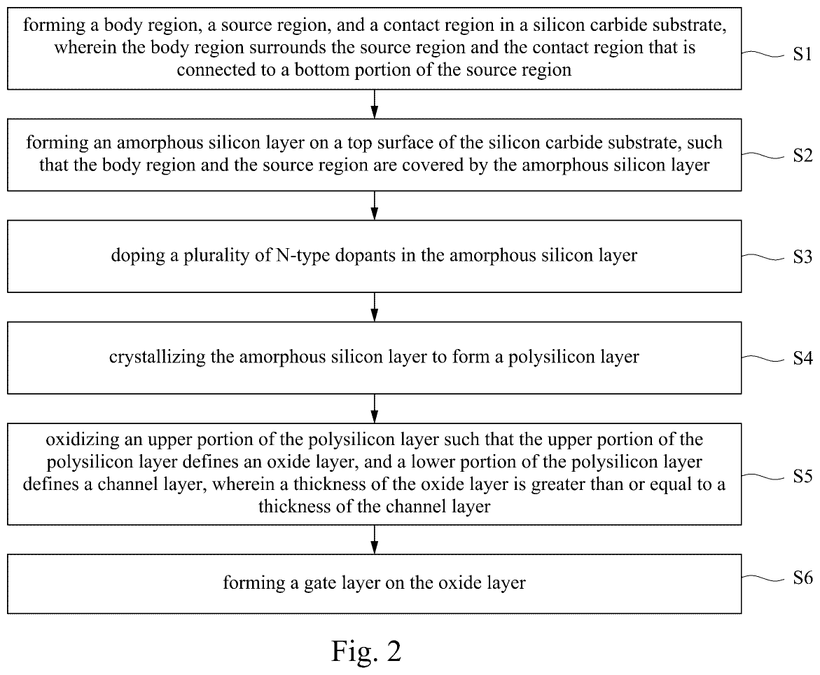

FIG. 2 is flow chart of a manufacturing method of a semiconductor device according to one embodiment of the present disclosure. In step S1, a body region, a source region, and a contact region are formed in a silicon carbide substrate, wherein the body region surrounds the source region and the contact region that is connected to a bottom portion of the source region. Thereafter, in step S2, an amorphous silicon layer is formed on a top surface of the silicon carbide substrate, such that the body region and the source region are covered by the amorphous silicon layer. Then, in step S3, a plurality of N-type dopants are doped in the amorphous silicon layer. Next, in step S4, the amorphous silicon layer is crystallized to form a polysilicon layer. Afterwards, in step S5, an upper portion of the polysilicon layer is oxidized such that the upper portion of the polysilicon layer defines an oxide layer, and a lower portion of the polysilicon layer defines a channel layer, wherein a thickness of the oxide layer is greater than or equal to a thickness of the channel layer. Subsequently, in step S6, a gate layer is formed on the oxide layer.

Each of aforementioned steps S1 to S6 may include plural detailed steps. The manufacturing method of the semiconductor device may further include other steps between step S1 and step S6, and may include other steps before step S1 and after step S6. In the following description, step S1 to step S6 described above will be explained in detail.

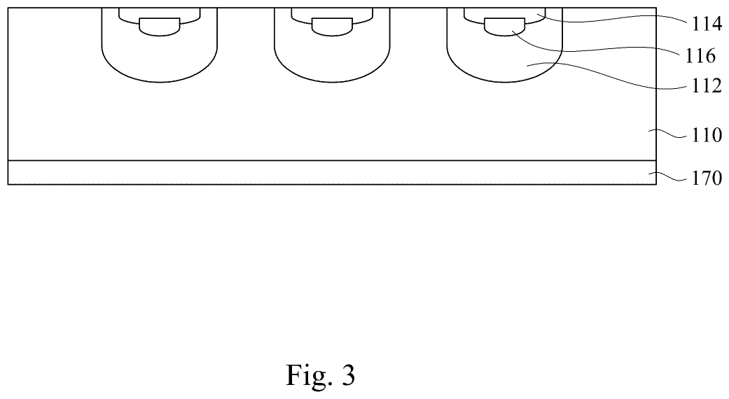

FIG. 3 to FIG. 8 are cross-sectional views at intermediate stages of a manufacturing method of a semiconductor device according to one embodiment of the present disclosure. As shown in FIG. 3, the body region 112, the source region 114, and the contact region 116 are formed in the silicon carbide substrate 110. The body region 112 is formed by doping P-type dopants (e.g., aluminum or boron) in the silicon carbide substrate 110 and annealing in a high temperature (e.g., 1700° C.). In some embodiments, the P-type dopants having a dose in a range from 1e16 cm⁻³ to 1e18 cm⁻³ are used to dope in the body region 112. The source region 114 may be formed by implanting N-type ions (e.g., nitrogen), and the contact region 116 may be formed by implanting P-type ions (e.g., aluminum). In addition, before the body region 112, the source region 114, and the contact region 116 are formed in the silicon carbide substrate 110, the drain layer 170 can be formed on the bottom surface of the silicon carbide substrate 110.

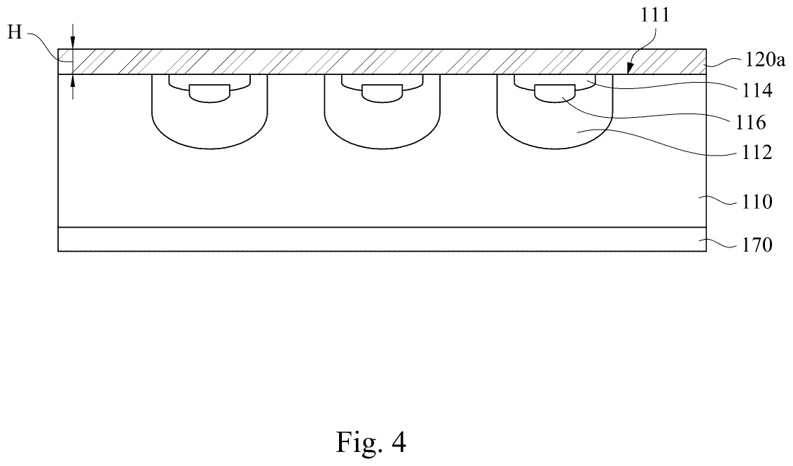

As shown in FIG. 4, thereafter, an amorphous silicon layer 120a is formed on the first top surface 111 of the silicon carbide substrate 110, such that the body region 112 and the source region 114 are covered by the amorphous silicon layer 120a. In some embodiments, the thickness H of the amorphous silicon layer 120a is in a range from 50 nm to 100 nm. Furthermore, the amorphous silicon layer 120a may be formed by deposition, such as chemical vapor deposition (CVD).

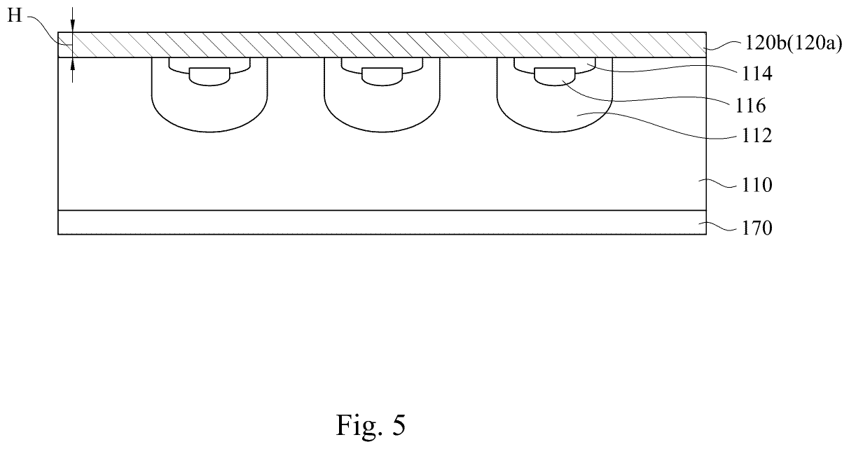

As shown in FIG. 5, after the formation of the amorphous silicon layer 120a, a plurality of N-type dopants can be doped in the amorphous silicon layer 120a. In some embodiments, the N-type dopants are doped in the amorphous silicon layer 120a by the dose of the N-type dopants in a range from 1e15 cm⁻³ to 1e17 cm⁻³. For example, the N-type dopants may be phosphorus or arsenic. After the N-type dopants are doped in the amorphous silicon layer 120a, the amorphous silicon layer 120a can be crystallized to form a polysilicon layer 120b. Crystallizing the amorphous silicon layer 120a may be performed by excimer laser annealing the amorphous silicon layer 120a.

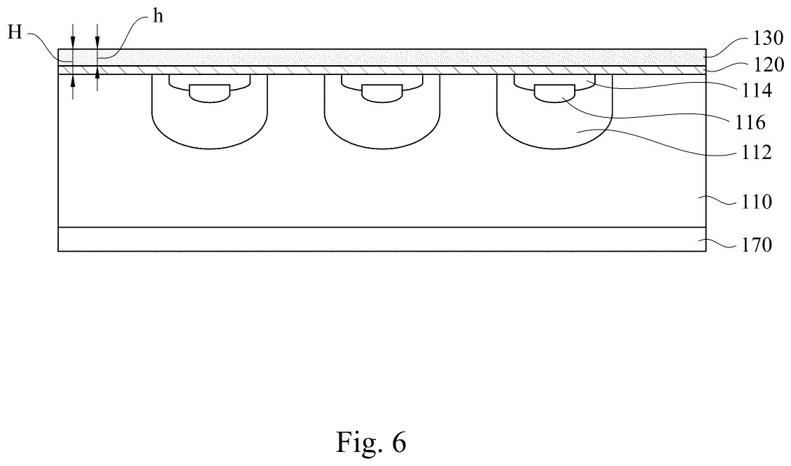

As shown in FIG. 5 and FIG. 6, after forming the polysilicon layer 120b, the an upper portion of the polysilicon layer 120b can be oxidized such that the upper portion of the polysilicon layer 120b defines the oxide layer 130, and the lower portion of the polysilicon layer 120b defines the channel layer 120. In other words, the channel layer 120 of FIG. 6 is the lower portion of the polysilicon layer 120b of FIG. 5, and the oxide layer 130 of FIG. 6 is formed by oxidizing the upper portion of the polysilicon layer 120b of FIG. 5. The thickness of the oxide layer 130 is greater than the thickness of the channel layer 120. In some embodiments, the thickness of the oxide layer 130 is in a range from 25 nm to 60 nm, and the sum of the thicknesses H of the oxide layer 130 and the channel layer 120 is in a range from 50 nm to 100 nm. In the step of oxidizing the upper portion of the polysilicon layer 120b, the upper portion of the polysilicon layer 120b can be oxidized by a temperature in a range from 750° C. to 900° C., which is a low-temperature oxidation process.

Specifically, since the manufacturing method of the semiconductor device is performed by forming the amorphous silicon layer 120a on the first top surface 111 of the silicon carbide substrate 110 and then doping the N-type dopants in the amorphous silicon layer 120a and crystallizing the amorphous silicon layer 120a to form the polysilicon layer 120b, the upper portion of the polysilicon layer 120b can be oxidized to form the oxide layer 130 and the lower portion of the polysilicon layer 120b serves as the channel layer 120.

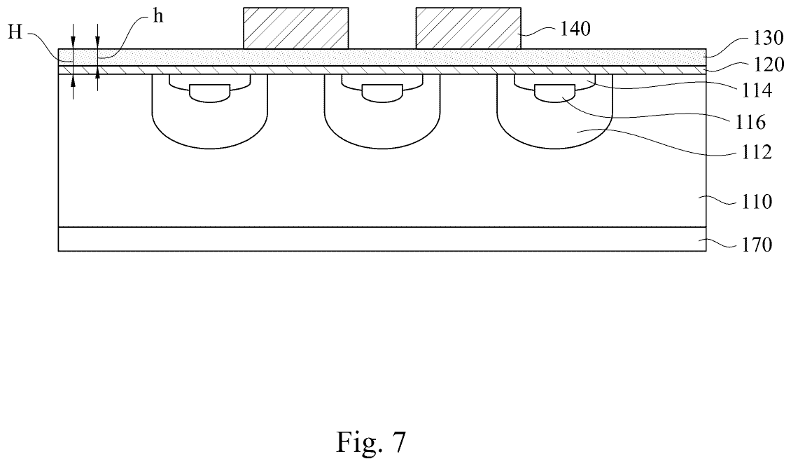

As shown in FIG. 7, after the formation of the oxide layer 130, the gate layer 140 can be formed on the oxide layer 130. In some embodiments, the material of the gate layer 140 may be polysilicon.

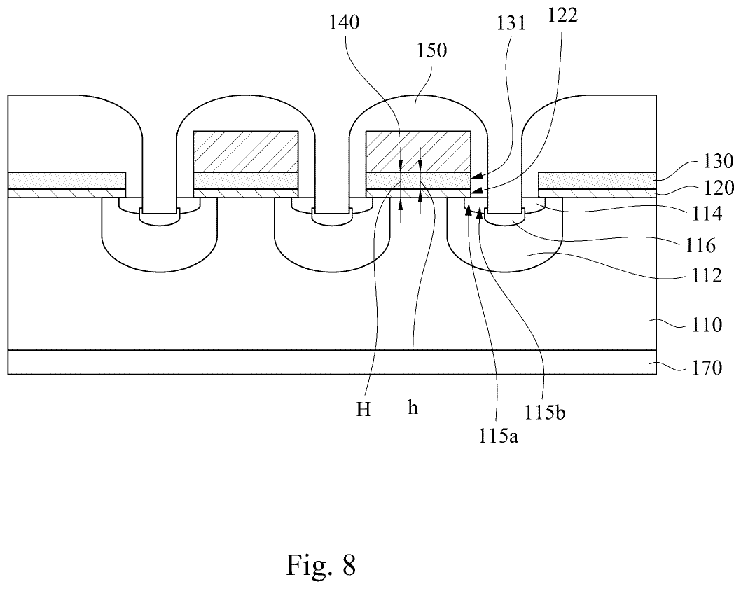

As shown in FIG. 8, after the gate layer 140 is formed on the oxide layer 130, the oxide layer 130 and the channel layer 120 that are above the source region 114 can be etched, such that the channel layer 120 covers the first portion 115a of the source region 114, and exposes the source region 114 except the first portion 115a. For example, the second portion 115b of the source region 114 is exposed. The oxide layer 130 may act as a gate dielectric layer. Thereafter, the interlayer dielectric layer 150 can be formed to cover the gate layer 140 and the second portion 115b of the source region 114, such that the interlayer dielectric layer 150 is in direct contact with the first sidewall 131 of the oxide layer 130 and the second sidewall 122 of the channel layer 120. Subsequently, the source region 114 on the contact region 116 is etched to expose the contact region 116, thereby obtaining the structure of FIG. 8.

As shown in FIG. 8 and FIG. 1, after forming the structure of FIG. 8, the metal layer 160 can be formed on the interlayer dielectric layer 150, and the metal layer 160 passes through the source region 114 to connect the contact region 116, and thus the semiconductor device 100 of FIG. 1 is formed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a silicon carbide substrate having a body region, a source region, and a contact region therein, wherein the body region surrounds the source region and the contact region, and the contact region connects a bottom portion of the source region;
a channel layer located on a first top surface of the silicon carbide substrate, and covering the body region and a first portion of the source region;
an oxide layer in direct contact with a second top surface of the channel layer, wherein a thickness of the oxide layer is greater than or equal to a thickness of the channel layer; and
a gate layer located on the oxide layer.

2. The semiconductor device of claim 1, further comprising:
an interlayer dielectric layer covering the gate layer and a second portion of the source region, and in direct contact with a first sidewall of the oxide layer and a second sidewall of the channel layer.

3. The semiconductor device of claim 2, further comprising:
a metal layer located on the interlayer dielectric layer and passing through the source region to connect the contact region.

4. The semiconductor device of claim 1, further comprising:
a drain layer located on a bottom surface of the silicon carbide substrate.

5. The semiconductor device of claim 1, wherein a material of the channel layer is polysilicon.

6. A manufacturing method of a semiconductor device, comprising:
forming a body region, a source region, and a contact region in a silicon carbide substrate, wherein the body region surrounds the source region and the contact region that is connected to a bottom portion of the source region;
forming an amorphous silicon layer on a top surface of the silicon carbide substrate, such that the body region and the source region are covered by the amorphous silicon layer;
doping a plurality of N-type dopants in the amorphous silicon layer;
crystallizing the amorphous silicon layer to form a polysilicon layer;
oxidizing an upper portion of the polysilicon layer such that the upper portion of the polysilicon layer defines an oxide layer, and a lower portion of the polysilicon layer defines a channel layer, wherein a thickness of the oxide layer is greater than or equal to a thickness of the channel layer; and
forming a gate layer on the oxide layer.

7. The manufacturing method of the semiconductor device of claim 6, wherein the body region is formed by doping a plurality of P-type dopants in the silicon carbide substrate.

8. The manufacturing method of the semiconductor device of claim 6, wherein the N-type dopants are doped in the amorphous silicon layer by a dose of the N-type dopants in a range from 1e15 cm⁻³ to 1e17 cm⁻³.

9. The manufacturing method of the semiconductor device of claim 6, wherein crystallizing the amorphous silicon layer is performed by excimer laser annealing the amorphous silicon layer.

10. The manufacturing method of the semiconductor device of claim 6, wherein oxidizing the upper portion of the polysilicon layer is performed by a temperature in a range from 750° C. to 900° C.

11. The manufacturing method of the semiconductor device of claim 6, wherein after the gate layer is formed on the oxide layer, the manufacturing method further comprises:
etching the oxide layer and the channel layer that are above the source region, such that the channel layer covers a first portion of the source region, and exposes the source region except the first portion.

12. The manufacturing method of the semiconductor device of claim 11, further comprising:
forming an interlayer dielectric layer to cover the gate layer and a second portion of the source region, such that the interlayer dielectric layer is in direct contact with a first sidewall of the oxide layer and a second sidewall of the channel layer.

13. The manufacturing method of the semiconductor device of claim 12, further comprising:
etching the source region on the contact region such that the contact region is exposed.

14. The manufacturing method of the semiconductor device of claim 13, further comprising:
forming a metal layer on the interlayer dielectric layer, wherein the metal layer passes through the source region to connect the contact region.

15. The manufacturing method of the semiconductor device of claim 6, wherein before the body region, the source region, and the contact region are formed in the silicon carbide substrate, the manufacturing method further comprises:
forming a drain layer on a bottom surface of the silicon carbide substrate.
